(19) United States
(12) Patent Application Publication
(10) Pub. No.: US 2025/0221321 A1
(43) Pub. Date: Jul. 3, 2025

(54) STRUCTURE, SUPERCONDUCTING DEVICE, AND METHOD FOR MANUFACTURING STRUCTURE

(71) Applicants: NATIONAL INSTITUTE OF ADVANCED INDUSTRIAL SCIENCE AND TECHNOLOGY, Tokyo (JP); NEC Corporation, Tokyo (JP)

(72) Inventors: Katsuya KIKUCHI, Tsukuba-shi (JP); Yuuki ARAGA, Tsukuba-shi (JP); Masahisa FUJINO, Tsukuba-shi (JP); Naoya WATANABE, Tsukuba-shi (JP); Wei FENG, Tsukuba-shi (JP); Hiroshi NAKAGAWA, Tsukuba-shi (JP); Akira MIYATA, Tokyo (JP); Ayami YAMAGUCHI, Tokyo (JP); Kenji NANBA, Tokyo (JP); Takanori NISHI, Tokyo (JP)

(21) Appl. No.: 19/084,483

(22) Filed: Mar. 19, 2025

Related U.S. Application Data
(63) Continuation of application No. PCT/JP2023/034553, filed on Sep. 22, 2023.

(30) Foreign Application Priority Data
Sep. 22, 2022 (JP) 2022-151962

(51) Int. Cl. H10N 60/82; H10N 60/01; H10N 60/10

(52) U.S. Cl. CPC H10N 60/82; H10N 60/01; H10N 60/10

(57) ABSTRACT

A structure includes a first substrate, a lower wire formed of a superconducting material and provided on the first substrate, a control post formed of a superconducting material including a metal and provided on the lower wire, an upper wire formed of a superconducting material and provided on the control post, and a second substrate provided on the upper wire. The control post includes a first electrode, a junction surface, and a second electrode, which is joined to the first electrode via the junction surface. The first and second electrodes are formed of the same type of metal.

### TECHNICAL FIELD

The present disclosure relates to a structure, a superconducting device, and a method for manufacturing a structure.

Priority is claimed based on Japanese Patent Application No. 2022-151962, filed on Sep. 22, 2022, the content of which is incorporated herein by reference.

### BACKGROUND

Simulation, measurement, and control using classical scientific techniques in the related art have limitations. Accordingly, with the advancement of new scientific technological techniques based on quantum scientific technology, it is important to solve discontinuous problem by clarifying the behavior of materials or the like in an electron level.

Patent Document 1 discloses a device that includes a first chip with a first circuit element, a first interconnection pad in electrical contact with the first circuit element, and a barrier layer on the first interconnection pad, wherein the barrier layer is formed of titanium nitride; and a second chip with a superconducting bump bond on the barrier layer and a first quantum circuit element joined to the first chip, wherein the superconducting bump bond provides an electrical connection between the first circuit element and the first quantum circuit element.

### CITATION LIST

### Patent Document

Patent Document 1: Japanese Patent No. 6742433

### SUMMARY

On the other hand, when a capacitive or inductive connection is used as an electrical connection between a superconducting chip and a superconducting interposer, precise height control is required. However, the method described in Patent Document 1 involves a melting connection using a bump, and thus the bump needs to be deformed by pressing or melting. Accordingly, there is a problem in that it is difficult to accurately control the height with the method described in Patent Document 1.

The following means provide a structure manufacturing method, a structure, and a superconducting device that enable more accurate height control.

### Solution to Problem

To achieve the aforementioned object, the present disclosure provides the following means.

(1) According to an aspect of the present disclosure, a structure is provided including: a first substrate; a lower wire provided on the first substrate and formed of a superconducting material; a control post provided on the lower wire and formed of a superconducting material including a metal; an upper wire provided on the control post and formed of a superconducting material; and a second substrate provided on the upper wire, wherein the control post includes a first electrode, a joining surface, and a second electrode joined to the first electrode via the joining surface, and the first electrode is formed of the same type of metal as the second electrode.

(7) According to another aspect of the present disclosure, a superconducting device is provided including the structure according to (1).

(8) According to another aspect of the present disclosure, a method for manufacturing structure is provided including: a first electrode forming step of forming a second electrode on a lower wire provided on a first substrate and formed of a superconducting material; a second electrode forming step of forming a first electrode on an upper wire provided on a second substrate and formed of a superconducting material; a surface activating step of activating surfaces of the first electrode and the second electrode using plasma or ion beams at 1.0×10⁻⁴ Pa or lower; and a joining step of joining the first electrode and the second electrode at 1.0×10⁻⁴ Pa or lower, wherein the first electrode is formed of a superconducting material including the same type of metal as the second electrode.

### BRIEF DESCRIPTION OF DRAWINGS

FIG. 1 A sectional view illustrating an example of a structure according to an embodiment of the present disclosure.

FIG. 2 A diagram schematically illustrating an example of a superconducting device according to the embodiment of the present disclosure.

FIG. 3 (a) A diagram schematically illustrating an Nb patterned substrate according to an example of the present disclosure and (b) a diagram schematically illustrating an example of an Nb patterned chip according to the example.

FIG. 4 An ultrasonic microscope image of joined Nb electrode portions.

FIG. 5 A diagram illustrating electrical characteristics (I-V) via a joining electrode interface of a joined body cooled at 0.3 K in a refrigerator.

FIG. 6 A diagram illustrating a resistance of the Nb electrode portion measured at the time of rising of the temperature.

### DETAILED DESCRIPTION

Hereinafter, the present disclosure will be described in conjunction with an embodiment of the invention, and the following embodiment does not limit the inventions described in the appended claims. All combinations of features described in the embodiment are not necessarily essential for the solution of the invention. In the drawings, the same or similar constituents will be referred to by the same reference signs, and repeated description thereof may be omitted. Shapes, sizes, and the like of constituents in the drawings may be exaggerated for the purpose of clearer explanation.

### <Structure 10>

A structure according to an embodiment of the present disclosure will be described below with reference to the drawings. The same constituents will be referred to by the same reference signs, and description thereof may be omitted.

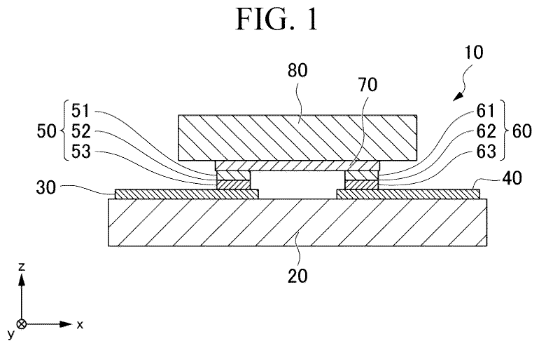

FIG. 1 is a diagram schematically illustrating an example of a structure according to an embodiment of the present disclosure. As illustrated in FIG. 1, a structure 10 according to the embodiment of the present disclosure includes a lower substrate 20, a first lower wire 30, a second lower wire 40, a first control post 50, a second control post 60, an upper wire 70, and an upper substrate 80. In the following description, for the purpose of convenience of explanation, a vertical direction of the structure 10 in FIG. 1 is defined as a z axis, and a plane perpendicular to the z axis is defined as an xy plane. That is, an in-plane direction of the lower substrate 20 in FIG. 1 is defined as an xy direction, and a direction perpendicular to the lower substrate 20 is defined as the z direction. A lateral direction of the structure 10 which is one direction in the xy plane is defined as an x axis, and a depth direction of the structure 10 is defined as a y axis. Upward and downward in the present embodiment are not limited by a direction in which the structure is used but are directions for the purpose of convenience of explanation. In the present embodiment, a side on which a value of the z axis increases in FIG. 1 is the upside. Specifically, the side on which the lower wires 30 and 40 are provided with respect to the lower substrate 20 is referred to as upward, and the side on which the lower substrate 20 is located with respect to the lower wires 30 and 40 is referred to as downward.

The first lower wire 30 and the second lower wire 40 are provided on the lower substrate 20. In FIG. 1, the first lower wire 30 and the second lower wire 40 are disposed to be in contact with the lower substrate 20. The first lower wire 30 and the second lower wire 40 are disposed not to be in contact but to be separated. The first control post 50 is provided on the first lower wire 30. In FIG. 1, the first control post 50 is disposed to be in contact with the first lower wire 30.

The second control post 60 is provided on the second lower wire 40. In FIG. 1, the second control post 60 is disposed to be in contact with the second lower wire 40. The first control post 50 and the second control post 60 are disposed not to be in contact but to be separated. The upper wire 70 is disposed on the first control post 50 and the second control post 60. The upper substrate 80 is provided on the upper wire 70. In FIG. 1, the upper wire 70 is disposed to be in contact with the first control post 50 and the second control post 60.

The first control post 50 includes a second electrode 51, a junction surface 52, and a first electrode 53. The first electrode 53 is in contact with the junction surface 52 and the second electrode 51. The second electrode 51 and the first electrode 53 are originally separate and are unified by joining. A boundary between the second electrode 51 and the first electrode 53 is the junction surface 52.

The second control post 60 includes a second electrode 61, a junction surface 62, and a first electrode 63. The first electrode 63 is in contact with the junction surface 62 and the second electrode 61. The second electrode 61 and the first electrode 63 are originally separate and are unified by joining. A boundary between the second electrode 61 and the first electrode 63 is the junction surface 62.

In the embodiment of the present disclosure, the first lower wire 30 and the second lower wire 40 are electrically connected via the upper wire 70. At a superconductive critical temperature (transition temperature) or lower, a superconducting current flows between the first lower wire 30 and the second lower wire 40 via the upper wire 70. As illustrated in FIG. 1, the upper substrate 80 is joined onto the lower substrate 20 in a flip-chip manner.

### (Lower Substrate 20)

In the present embodiment, the lower substrate 20 is an interposer. The lower substrate 20 can be formed of, for example, a material which is generally used for a substrate of a metal superconducting device such as silicon or sapphire. In the lower substrate 20, active elements such as logics, memories, sensors, or actuators may be formed on a substrate of silicon or the like. The interposer is also referred to as an interposer chip.

### (First Lower Wire 30)

In the present embodiment, the first lower wire 30 is formed of a superconducting material. The first lower wire 30 may be a superconducting wire formed of a metal. A metal superconductor such as niobium, niobium nitride, aluminum, indium, rhenium, tantalum, or titanium nitride may be used as the material of the first lower wire 30.

### (First Control Post 50)

In the present embodiment, the first control post 50 is formed of a superconducting material including a metal. Examples of the superconducting material including a metal include In, Nb, Al, and Ta. The first control post 50 controls a distance between the lower substrate 20 and the upper substrate 80. The first control post 50 electrically connects the first lower wire 30 and the upper wire 70. At a superconductive critical temperature or lower, a superconducting current flows between the first lower wire 30 and the upper wire 70 via the control post.

In a flip-chip connection according to the related art, a control post is provided separately from a wire electrically connecting an upper device and a lower device. Accordingly, the control post according to the related art is formed of a material not having electric conductivity. On the other hand, in the present embodiment, the first control post 50 has a role in controlling the distance between the lower substrate 20 and the upper substrate 80 and a role in electrically connecting the first lower wire 30 and the upper wire 70. Accordingly, a control post does not need to be provided separately from a wire electrically connecting an upper device and a lower device. As a result, with a wire electrically connecting an upper device and a lower device in a flip-chip connection manner, it is possible to more accurately control the distance between the lower substrate 20 and the upper substrate 80 without separately providing a control post.

The second electrode 51 and the first electrode 53 are formed of a superconducting material including a metal. Examples of the superconducting material including a metal include In, Nb, Al, and Ta. The second electrode 51 and the first electrode 53 may be formed of a superconducting material including one metal selected from a group consisting of In, Nb, Al, and Ta. The second electrode 51 is formed of the same type of metal as the first electrode 53. Accordingly, the second electrode 51 and the first electrode 53 can be directly joined. That is, without providing a barrier layer preventing diffusion of elements from the second electrode 51 to the first electrode 53 or from the first electrode 53 to the second electrode 51 between the second electrode 51 and the first electrode 53, a superconducting current flows between the second electrode 51 and the first electrode 53. When a barrier layer is not provided between the second electrode 51 and the first electrode 53, it means that a thickness of a layer other than the material of the second electrode 51 and the first electrode 53 between the second electrode 51 and the first electrode 53 is equal to or less than 0.5 nm. A junction in which the second electrode 51 and the first electrode 53, which are separate members, can be joined is the junction surface 52. The surface roughness Ra of the junction surface 52 may be equal to or less than 1.0 nm. The surface roughness Ra of the junction surface 52 can be measured using X-ray reflectometry (XRR).

In a flip-chip connection according to the related art, an upper device and a lower device are joined by a melting connection using a bump. However, in the melting connection using a bump, the bump needs to be crushed through pressing or melting, and thus it is difficult to accurately control the height. On the other hand, with the structure 10 according to the present embodiment, it is not necessary to perform a melting connection using a bump. Accordingly, with the structure 10 according to the present embodiment, it is possible to more accurately control the distance between the lower substrate 20 and the upper substrate 80.

### (Second Lower Wire 40)

In the present embodiment, the second lower wire 40 is formed of a superconducting material. The second lower wire 40 may be a superconducting wire formed of a metal. A metal superconductor such as niobium, niobium nitride, aluminum, indium, rhenium, tantalum, or titanium nitride may be used as the material of the second lower wire 40. The second lower wire 40 may be formed of the same type of metal as the first lower wire 30. As illustrated in FIG. 1, the second lower wire 40 is not in direct contact with the first lower wire 30.

### (Second Control Post 60)

In the present embodiment, the second control post 60 is formed of a superconducting material including a metal. Examples of the superconducting material including a metal include In, Nb, Al, and Ta. The second control post 60 controls the distance between the lower substrate 20 and the upper substrate 80. The second control post 60 electrically connects the second lower wire 40 and the upper wire 70. At a superconductive critical temperature or lower, a superconducting current flows between the second lower wire 40 and the upper wire 70 via the control post. As illustrated in FIG. 1, the second control post 60 is not in direct contact with the first control post 50. That is, the first control post 50 and the second control post 60 are disposed to be separated from each other.

In the present embodiment, the second control post 60 has a role in controlling the distance between the lower substrate 20 and the upper substrate 80 and a role in electrically connecting the second lower wire 40 and the upper wire 70. Accordingly, a control post does not need to be provided separately from a wire electrically connecting an upper device and a lower device. As a result, with a wire electrically connecting an upper device and a lower device in a flip-chip connection manner, it is possible to more accurately control the distance between the lower substrate 20 and the upper substrate 80 without separately providing a control post.

The second electrode 61 and the first electrode 63 are formed of a superconducting material including a metal. Examples of the superconducting material including a metal include In, Nb, Al, and Ta. The second electrode 61 is formed of the same type of metal as the first electrode 63. The second electrode 61 and the first electrode 63 may be formed of the same type of metal as the second electrode 51 and the first electrode 53. Configurations, operations, and advantages of the second electrode 61 and the first electrode 63 other than described above are the same as the second electrode 51 and the first electrode 53.

### (Upper Wire 70)

In the present embodiment, the upper wire 70 is formed of a superconducting material. The upper wire 70 may be a superconducting wire formed of a metal. A metal superconductor such as niobium, niobium nitride, aluminum, indium, rhenium, tantalum, or titanium nitride may be used as the material of the upper wire 70. The upper wire 70 may be formed of the same type of metal as the second lower wire 40 and the first lower wire 30. As illustrated in FIG. 1, the upper wire 70 is in contact with the first control post 50 and the second control post 60. The first control post 50 is electrically connected to the second control post 60 via the upper wire 70. At a superconductive critical temperature or lower, a superconducting current flows between the first control post 50 and the second control post 60 via the upper wire 70.

The material of the upper wire 70 may be the same as or different from those of the first control post 50 and the second control post 60. When the material of the upper wire 70 is different from the materials of the first control post 50 and the second control post 60, a barrier layer may be provided between the upper wire 70 and the first control post 50 and between the upper wire 70 and the second control post 60. At a superconductive critical temperature or lower, the material and the thickness of the barrier layer are not particularly limited as long as a superconducting current flows between the upper wire 70 and the first control post 50 and between the upper wire 70 and the second control post 60.

The material of the upper wire 70 may be the same as that of the first control post 50 and the second control post 60. Accordingly, a barrier layer does not have to be provided between the upper wire 70 and the first control post 50 and between the upper wire 70 and the second control post 60. As a result, it is possible to more accurately control the distance between the upper wire 70 and the lower wire.

### (Upper Substrate 80)

In the present embodiment, the upper substrate 80 is a quantum beat chip. Similarly to a general semiconductor chip, for example, silicon may be used as a material of the quantum beat chip. As the quantum beat chip, a plurality of quantum beat chips may be arranged in a planar direction. The quantum beat chip may include a plurality of circuit elements for performing data processing. Each circuit element may be a quantum circuit element. The quantum circuit elements may be configured to perform computation using a nondeterministic method on the basis of quantum mechanical phenomena such as quantum superposition and quantum entanglement. The quantum circuit elements may be configured to operate to simultaneously express information of a plurality of states. Examples of the quantum circuit element include a superconducting coplanar waveguide, a quantum oscillator, a flux quantum beat, and a superconducting quantum interference device (SQUIDS).

In the structure 10 according to the embodiment of the present disclosure, a junction portion for a capacitance connection or an inductance connection may be provided between the upper substrate 80 and the lower substrate 20. Part of the control posts 50 and 60 in contact with the lower wire 20 may be referred to as a first electrode portion, and a part in contact with the upper wire 70 may be referred to as a second electrode portion.

### <Superconducting Device 100>

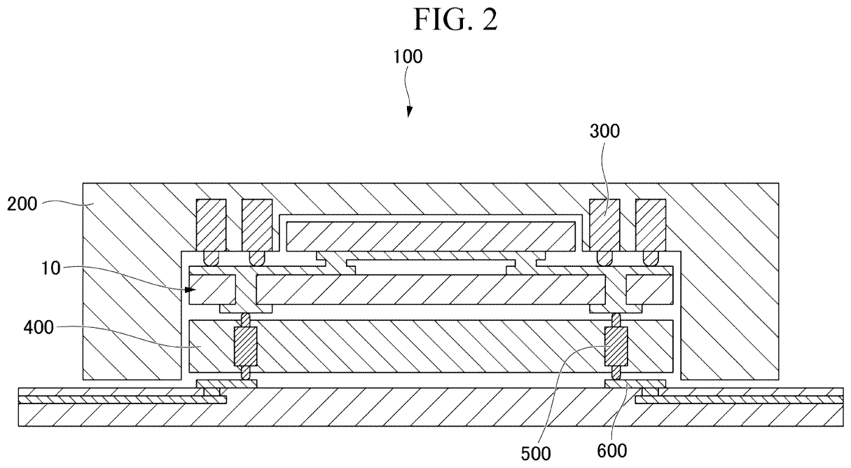

A superconducting device according to the embodiment of the present disclosure will be described below. FIG. 2 is a diagram schematically illustrating an example of a superconducting device according to the embodiment of the present disclosure. The same constituents as in the aforementioned embodiment may be referred to by the same reference signs, and description thereof may be omitted. As illustrated in FIG. 2, the superconducting device 100 according to the embodiment of the present disclosure includes the structure 10 according to the embodiment of the present disclosure, a flip-chip cover portion 200, a cover-side pressing spring portion 300, an aluminum package portion 400, a signal contact probe 500, and a waveguide 600. In the present embodiment, the structure 10 is a quantum bit integrated circuit connected in a flip-chip manner.

As illustrated in FIG. 2, the quantum beat integrated circuit chip includes a superconducting through-silicon via.

The superconducting device according to the embodiment of the present disclosure can be used in the fields of supersensitive magnetometry, superconductive digital integrated circuit, quantum computer, and the like. An example of a superconducting device in the field of supersensitive magnetometry is a superconducting quantum interference device (SQUID). An example of a superconducting device in the field of superconductive digital integrated circuits is a rapid single-flux quantum (RSFQ). Examples of a superconducting device in the field of quantum computer include a superconducting annealing type quantum computer and a superconducting gate type quantum computer.

### <Structure Manufacturing Method>

A structure manufacturing method according to the embodiment will be described below. The structure manufacturing method according to the embodiment of the present disclosure includes the following steps:
(a) a step of forming a first electrode on a lower wire provided on a first substrate and formed of a superconducting material (a first electrode forming step);
(b) a step of forming a second electrode on an upper wire provided on a second substrate and formed of a superconducting material (a second electrode forming step);
(c) a step of activating surfaces of the first electrode and the second electrode using plasma or ion beams at 1.0×10⁻⁴ Pa or lower (a surface activating step); and
(d) a step of joining the first electrode and the second electrode at 1.0×10⁻⁴ Pa or lower (a joining step).

Here, the first electrode is formed of a superconducting material including the same type of metal as the second electrode.

Here, the first substrate corresponds to the lower substrate 20 in the structure 10, and the second substrate corresponds to the upper substrate 80 in the structure 10. The structure manufacturing method according to the present embodiment does not limit a direction at the time of manufacturing. The order of (a) the first electrode forming step and (b) the second electrode forming step is arbitrary, and any step may be first performed.

### (First Electrode Forming Step)

In the first electrode forming step, the first electrode is formed on the lower wire. As a preliminary step of the first electrode forming step, a lower wire forming step of forming the lower wire on a first substrate, which is the lower substrate in a product, may be performed before the first electrode forming step.

A method of providing the lower wire on the first substrate is, for example, a joining method such as bonding. The method of providing the first electrode on the lower wire is not particularly limited and is, for example, a joining method such as bonding. A method in which deposition and patterning are combined may be employed.

The first substrate may be an interposer. The first substrate can be formed of, for example, a material which is generally used for a substrate of a metal superconducting device such as silicon or sapphire. In the first substrate, active elements such as logics, memories, sensors, or actuators may be formed on a substrate of silicon or the like. The interposer is also referred to as an interposer chip.

The first lower wire is formed of a superconducting material. The first lower wire may be a superconducting wire formed of a metal. A metal superconductor such as niobium, niobium nitride, aluminum, indium, rhenium, tantalum, or titanium nitride may be used as the material of the first lower wire.

The first electrode is formed of a superconducting material including a metal. Examples of the superconducting material including a metal include In, Nb, Al, and Ta. The lower wire may be formed of the same material as the first electrode. Accordingly, it is not necessary to form a barrier layer for preventing diffusion of elements between the lower wire and the first electrode. As a result, it is possible to more accurately control the distance between the first substrate and the second substrate.

### (Second Electrode Forming Step)

Subsequently, the second electrode forming step is performed.

In the second electrode forming step, the second electrode is formed on the upper wire. As a preliminary step of the second electrode forming step, an upper wire forming step of forming the upper wire on a second substrate, which is the upper substrate in a product, may be performed before the second electrode forming step. Formation of the upper wire and formation of the second electrode may be successively performed.

A method of providing the upper wire on the second substrate is, for example, a joining method such as bonding. The method of providing the second electrode on the upper wire is not particularly limited and is, for example, a joining method such as bonding. A method in which deposition and patterning are combined may be employed.

The upper wire is formed of a superconducting material. The upper wire may be a superconducting wire formed of a metal. A metal superconductor such as niobium, niobium nitride, aluminum, indium, rhenium, tantalum, or titanium nitride may be used as the material of the upper wire.

The second substrate may be a quantum beat chip. Similarly to a general semiconductor chip, for example, silicon may be used as a material of the quantum beat chip. As the quantum beat chip, a plurality of quantum beat chips may be arranged in a planar direction. The quantum beat chip may include a plurality of circuit elements for performing data processing. Each circuit element may be a quantum circuit element. Examples of the quantum circuit element include a superconducting coplanar waveguide, a quantum LC oscillator, a flux quantum beat, and a superconducting quantum interference device (SQUIDS).

The second electrode is formed of a superconducting material including a metal. Examples of the superconducting material including a metal include In, Nb, Al, and Ta. The upper wire may be formed of the same material as the second electrode. Accordingly, it is not necessary to form a barrier layer for preventing diffusion of elements between the upper wire and the second electrode. As a result, it is possible to more accurately control the distance between the first substrate and the second substrate.

### (Smoothing Step)

A smoothing step may be performed after the first electrode forming step and the second electrode-forming step. In the smoothing step, surfaces which are joined in the subsequent joining step out of surfaces of the first electrode and the second electrode are smoothed. The smoothing step may be performed such that the surface roughness Ra of the surfaces joined to each other in the joining step is equal to or less than 1.0 nm. The surface roughness Ra can be measured using X-ray reflectometry (XRR).

(Surface activating step)

Subsequently, the surface activating step is performed.

In the surface activating step, the surfaces of the first electrode and the second electrode are activated at 1.0×10⁻⁴ Pa or lower using plasma or ion beams. For example, by applying plasma or ion beams to the surfaces of the first electrode and the second electrode, the surfaces of the first electrode and the second electrode are activated. When a natural oxide layer is formed on the surfaces of the first electrode and the second electrode, the natural oxide layer is removed by the plasma or ion beams. When the plasma or ion beams are applied to the surfaces of the first electrode and the second electrode, the pressure of the atmosphere is equal to or less than 1.0×10⁻⁴ Pa.

### (Joining Step)

Subsequently, the joining step is performed.

In the joining step, the first electrode and the second electrode are joined in an environment in which the pressure of the atmosphere is equal to or less than 1.0×10⁻⁴ Pa.

Specifically, the first electrode and the second electrode are joined such that the surfaces activated using plasma or ion beams out of the surfaces of the first electrode and the surfaces of the second electrode come into contact with each other. The temperature at which the first electrode and the second electrode may be joined be equal to or lower than melting points of the materials of the first electrode and the second electrode. Accordingly, the first electrode and the second electrode are not melted. As a result, it is possible to more accurately control the distance between the first substrate and the second substrate. The temperature at which the first electrode and the second electrode are joined may be equal to or lower than 100° C. Accordingly, it is possible to more accurately control the distance between the first substrate and the second substrate. Here, the temperature is the temperature of the first electrode and the second electrode in the joining step.

In the joining step, a load of 60 μN/m² may be applied to the junction surface between the first electrode and the second electrode. Accordingly, it is possible to more reliably join the first electrode and the second electrode. A difference between the total thickness of the first electrode and the second electrode after joining and the total thickness of the first electrode and the second electrode before joining may be equal to or less than 10 μm, and the first electrode and the second electrode may have the same thickness. Accordingly, it is possible to more accurately control the distance between the first substrate and the second substrate.

According to the present disclosure, it is possible to provide a structure manufacturing method, a structure, and a superconducting device with which more accurate height control can be achieved.

(2) In the structure according to (1), the lower wire and the upper wire may be formed of a superconducting material including the same type of metal as the first electrode and the second electrode.

(3) In the structure according to (1) or (2), a surface roughness Ra of the joining surface may be equal to or less than 1.0 nm.

(4) In the structure according to any one of (1) to (3), a distance between the upper wire and the lower wire may be equal to or less than 10 μm.

(5) In the structure according to any one of (1) to (4), the first electrode and the second electrode may be formed of In, Nb, Al, or Ta.

(6) In the structure according to any one of (1) to (5), the lower wire may include a first lower wire provided on the first substrate and a second lower wire provided on the first substrate, the control post may include a first control post provided on the first lower wire and a second control post provided on the second lower wire, and the upper wire may be provided on the first control post and the second control post.

(7) According to another aspect of the present disclosure, a superconducting device is provided including the structure according to any one of (2) to (6).

(9) In the method for manufacturing structure according to (8), the lower wire and the upper wire may be formed of the same type of metal as the first electrode and the second electrode.

(10) In the method for manufacturing structure according to (8) or (9), the first electrode and the second electrode may be formed of a superconducting material including one metal selected from a group consisting of In, Nb, Al, or Ta.

In the entire specification, when it is mentioned that a part “includes” or “has” an element, it means that another element is excluded but another element is included unless mentioned otherwise.

The term “portion” in this specification means a unit for processing at least one function or operation, and this may be realized by hardware or software or may be realized in a combination of hardware and software.

Elements in the embodiment can be appropriately replaced with known elements without departing from the gist of the present disclosure. The aforementioned modifications may be appropriately combined.

### Examples

Advantageous effects of the present disclosure will be specifically described below in conjunction with examples. Conditions in the examples are condition examples which were employed to ascertain the practicability and advantages of the present disclosure, and the present disclosure is not limited to these conditions. The present disclosure can employ various conditions as long as the objective can be achieved without departing from the gist thereof.

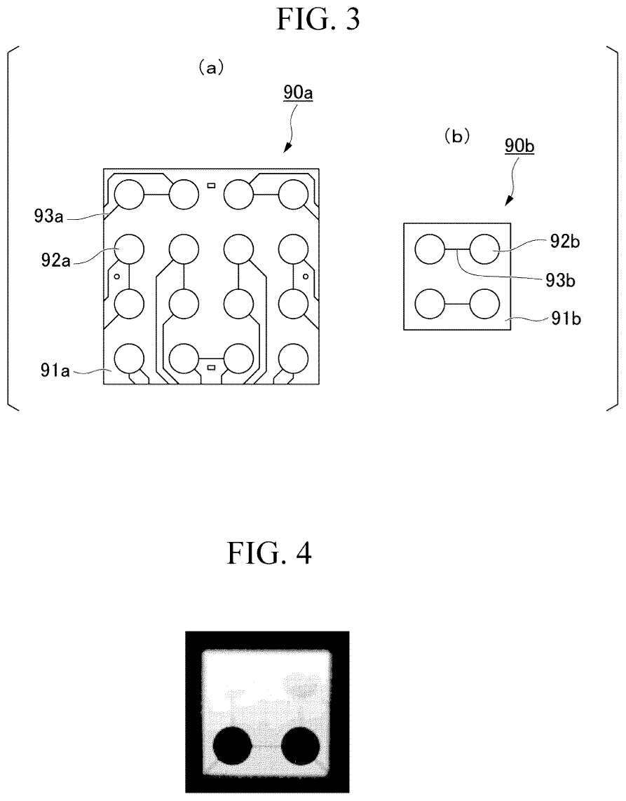

(a) of FIG. 3 is a diagram schematically illustrating an Nb patterned substrate 90a according to an example of the present disclosure, and (b) of FIG. 3 is a diagram schematically illustrating an example of an Nb patterned chip 90b according to the example of the present disclosure. In the Nb patterned substrate 90a and the Nb patterned chip 90b illustrated in FIG. 3, reference signs 91a and 91b denote Si substrates, reference signs 92a and 92b denote Nb joining electrodes, reference signs 93a and 93b denote Nb wires. The joining electrodes 92a and 92b are formed on the Nb wires 93a and 93b, respectively. The Si substrates 91a and 91b correspond to the lower substrate 20 and the upper substrate 80. The Nb joining electrode 92a corresponds to the first electrodes 53 and 63, and the Nb joining electrode 92b corresponds to the second electrodes 51 and 61. The Nb wire 93a corresponds to the first lower wire 30 and the second lower wire 40. The Nb wire 93b corresponds to the upper wire 70.

The Nb patterned substrate and the Nb patterned chip illustrated in FIG. 3 were manufactured using the following method.

First, the first substrate and the second substrate were prepared.

In the first electrode forming step and the second electrode forming step, a film of Nb, which is a superconducting metal, was formed and patterned on the Si substrates (the first substrate and the second substrate) 91a and 91b. Through this film formation and patterning, the wire 93a and the joining electrode 92a were formed on the first substrate 91a, and the wire 93b and the joining electrode 92b were formed on the second substrate 91b. The Nb joining electrodes 92a and 92b had a diameter of 1.4 mm. The total thickness of the joining electrodes 92a and 92b and the wires 93a and 93b was about 200 nm. The smoothing process was performed on the surfaces of the joining electrodes 92a and 92b, and the surface roughness Ra thereof was 0.53 nm. The surface roughness was measured using X-ray reflectometry (XRR). The substrate and the chip in which the joining electrodes and the wires were disposed were joined using a surface activation and joining device through surface activation using ion beams (the surface activating step) and load application (the joining step). In the surface activating step and the joining step, the inside of the surface activation and joining device was maintained in the vacuum atmosphere of 1.0×10⁻⁴ Pa.

FIG. 4 illustrates an ultrasonic microscope image of joined Nb electrode portions. As illustrated in FIG. 4, since the Nb electrode portion in the lower part of the image is black, it can be seen that joining between the Nb electrode portions was performed well without any clearance.

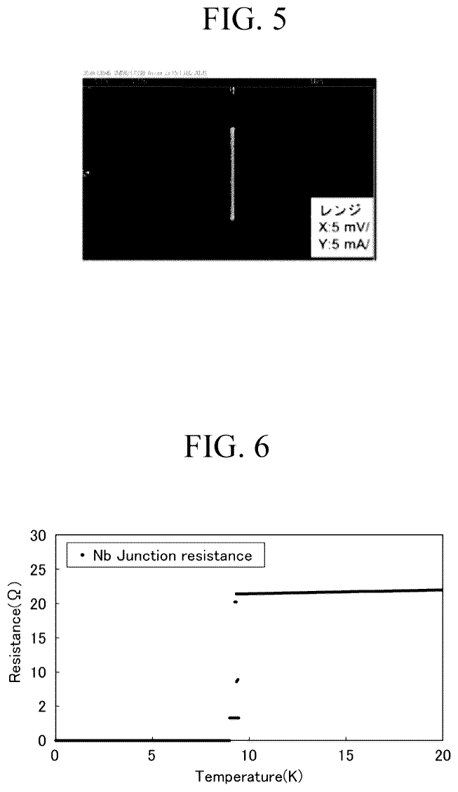

After the joining, wires for evaluating electrical characteristics were formed in extraction wiring portions of the Nb patterned substrate and chip, and electrical characteristics via a joining interface therebetween at the time of cooling in a 0.3 K refrigerator and at the time of rising of the temperature were evaluated. FIG. 5 is a diagram illustrating electrical characteristics (I-V) via a joining electrode interface of a joined body cooled at 0.3 K in a refrigerator. As illustrated in FIG. 5, a superconducting current equal to or greater than a critical current Ic=10 mA was ascertained in the joined body cooled at 0.3 K.

FIG. 6 is a diagram illustrating a resistance of the Nb electrode portion measured at the time of rising of the temperature. In FIG. 6, the horizontal axis represents the temperature, and the vertical axis represents a resistance. As illustrated in FIG. 6, the superconducting transition temperature Tc was estimated to be 9.3 K, and it was ascertained that the estimated temperature matched a theoretical value (Tc=9.29 K) of the superconducting transition temperature of Nb.

### INDUSTRIAL APPLICABILITY

According to the aforementioned embodiment of the present disclosure, it is possible to provide a structure manufacturing method, a structure, and a superconducting device with which more accurate height control can be achieved, which provides high industrial applicability.

### REFERENCE SIGNS LIST

10 Structure
30 First lower wire
40 Second lower wire
50 First control post
51 Second electrode
52 Junction surface
53 First electrode
60 Second control post
61 Second electrode
62 Junction surface
63 First electrode
70 Upper electrode
100 Superconducting device

What is claimed is:

1. A structure comprising:
a first substrate;
a lower wire provided on the first substrate and formed of a superconducting material;
a control post provided on the lower wire and formed of a superconducting material including a metal;
an upper wire provided on the control post and formed of a superconducting material; and
a second substrate provided on the upper wire,
wherein the control post includes a first electrode, a junction surface, and a second electrode joined to the first electrode via the junction surface, and
wherein the first electrode is formed of the same type of metal as the second electrode.

2. The structure according to claim 1, wherein the lower wire and the upper wire are formed of a superconducting material including the same type of metal as the first electrode and the second electrode.

3. The structure according to claim 1, wherein a surface roughness Ra of the junction surface is equal to or less than 1.0 nm.

4. The structure according to claim 1, wherein a distance between the upper wire and the lower wire is equal to or less than 10 μm.

5. The structure according to claim 1, wherein the first electrode and the second electrode are formed of In, Nb, Al, or Ta.

6. The structure according to claim 1, wherein the lower wire includes a first lower wire provided on the first substrate and a second lower wire provided on the first substrate,
wherein the control post includes a first control post provided on the first lower wire and a second control post provided on the second lower wire, and
wherein the upper wire is provided on the first control post and the second control post.

7. A superconducting device comprising the structure according to claim 1.

8. A method for manufacturing structure, comprising:
a first electrode forming step of forming a first electrode on a lower wire provided on a first substrate and formed of a superconducting material;
a second electrode forming step of forming a second electrode on an upper wire provided
on a second substrate and formed of a superconducting material;
a surface activating step of activating surfaces of the first electrode and the second electrode using plasma or ion beams at 1.0×10⁻⁴ Pa or lower; and
a joining step of joining the first electrode and the second electrode at 1.0×10⁻⁴ Pa or lower,
wherein the first electrode is formed of a superconducting material including the same type of metal as the second electrode.

9. The method for manufacturing structure according to claim 8, wherein the lower wire and the upper wire are formed of the same type of metal as the first electrode and the second electrode.

10. The method for manufacturing structure according to claim 8, wherein the first electrode and the second electrode are formed of a superconducting material including one metal selected from a group consisting of In, Nb, Al, or Ta.
